(19) United States
(12) Patent Application Publication
(10) Pub. No.: US 2024/0278320 A1
(43) Pub. Date: Aug. 22, 2024

(54) METHOD FOR MANUFACTURING A COOLING DEVICE

(71) Applicant: Miba Sinter Austria GmbH, Laakirchen (AT)

(72) Inventors: Manuel POHN, Lenzing (AT); Robert HELLEIN, Ungenach (AT)

(73) Assignee: Miba Sinter Austria GmbH, Laakirchen (AT)

(21) Appl. No.: 18/436,142

(22) Filed: Feb. 8, 2024

(30) Foreign Application Priority Data
Feb. 17, 2023 (AT) A50106/2023

(51) Int. Cl. B22F 3/16; B22F 5/00; F28F 21/08

(52) U.S. Cl. CPC B22F 3/164; F28F 21/081; B22F 2005/005

(57) ABSTRACT

A method for manufacturing a cooling device includes the steps of providing a material and forming a cooling structure from the material, wherein a sintering powder is used as the material from which a green body is manufactured by pressing, which is sintered into a preform, and the cooling structure in the form of cooling elements is manufactured from the preform by deformation, whereby a part of the preform is pressed through the mold.

### CROSS REFERENCE TO RELATED APPLICATIONS

Applicant claims priority under 35 U.S.C. § 119 of Austrian Application No. A50106/2023 filed Feb. 17, 2023, the disclosure of which is incorporated by reference.

### BACKGROUND OF THE INVENTION

### 1. Field of the Invention

The invention relates to a method for manufacturing a cooling device comprising the steps of providing a material and forming a cooling structure from the material.

Furthermore, the invention relates to a cooling device for cooling components comprising a base element with a first surface, and with a cooling structure comprising cooling elements which is arranged on the base element such as to protrude beyond the first surface.

### 2. Description of the Related Art

What are known as power electronics components, such as power semiconductors, are sufficiently known in the prior art. Such components are used frequently, for instance in motor vehicles. It is also known that during operation these components generate high levels of heat which often has to be discharged using a cooling medium. A wide variety of coolers for this purpose are known in the art.

For example, DE 11 2007 000 829 B4 describes an arrangement consisting of an inverter and a cooler for cooling the inverter, wherein the cooler comprises the following: a substrate that has a surface upon which the inverter is arranged; heat emitting components which are mounted on another, opposing surface of the substrate and which surrounds a region which is opposite to a region in which the inverter is arranged on the one surface of the substrate; a main pipe which is positioned at a distance from the other surface of the substrate and delimits a space which is between the main pipe and the substrate and which is configured such that a coolant can be fed to it and that it enables the coolant to come into contact with the heat emitting components; and a subsidiary pipe which protrudes from the main pipe to the substrate and which is opposite the region of the substrate in which the inverter is arranged, such that it causes a coolant fed to the main pipe to impinge on the other surface of the substrate in the region which is opposite the region in which the inverter is arranged, wherein the coolant fed to the main pipe is separated from the coolant fed to the space until it is discharged from the subsidiary pipe.

What are known as pin fin heat sinks have also been described in the prior art, in which a coolant is circulated thereby transferring the heat from the pins to the coolant. For example, DE 10 2019 108 106 A1 describes a cooler for a power semiconductor in an inverter, wherein the cooler has a two-part configuration and comprises: a base plate as the first part which can be connected to the power semiconductor in a heat-conducting manner; a heat sink as a second part which is arranged on the base plate, wherein the heat sink has at least an undulating recess which is configured continuously from a side of the heat sink which faces away from the base plate to a side facing the heat sink; wherein the first and second part are connected with one another and are coated with a layer which protects both parts from electrochemical reduction.

A device for cooling components is known from DE 10 2018 216 859 A1 which comprises: a first and a second base body; cylindrical and/or conical first cooling fins configured in the first base body in which a coolant can be circulated, and cylindrical and/or conical second cooling fins configured in the second base body in which a coolant can be circulated, wherein the second base body is fused with the first base body in such a way that the second cooling fins come to rest between the first cooling fins without touching the first base body.

### SUMMARY OF THE INVENTION

The object of the present invention is to be able to manufacture a cooling device for components in a resource-friendly manner.

The object of the invention is solved by the method disclosed at the beginning, according to which it is provided that a sintering powder is used as the material from which a green body is manufactured by pressing, that the green body is sintered into a preform, and the cooling structure in the form of cooling elements is manufactured from the preform by deformation, whereby a part of the preform is pressed through a mold.

Furthermore, the object of the invention is solved by the cooling device disclosed at the beginning, in which the base element and the cooling elements consist of a sintering material and the cooling elements are manufactured by deforming the base element material.

It is thereby advantageous that by deforming the base element into cooling elements, no waste material is generated in their manufacture, as would be the case with machining. Moreover, all cooling elements of the cooling device can be manufactured simultaneously, meaning a corresponding increase in productivity can be achieved. It is thereby advantageous for the deformation that the preform, although it already has a certain strength from sintering, is more easily deformable due to pores than a solid material.

According to one embodiment of the invention, it can be provided that the preform is re-pressed and that the cooling structure is formed during re-pressing. The combination of these steps into a single method step achieves a corresponding reduction of the manufacturing time for the cooling device. It is thereby advantageous that since the preform is not previously re-pressed, it can be deformed into a cooling structure more easily due to the high proportion of pores.

According to a further embodiment of the invention it can be provided that the cooling structure in the form of pin-shaped cooling elements is manufactured using a perforated plate as a mold. The mold can thereby be configured relatively simply. Moreover, it is easily adaptable to different shaped cooling elements. Surprisingly, despite the large contact surface, ejecting the cooling elements from the mold by removing the perforated plate does not present any problems with regard to material breakages.

According to a further embodiment of the invention, it can be provided that the surface of the preform upon which the cooling structure is formed is produced to be at least partially arched. An improved “flow behavior” of the material for manufacturing the cooling structure is thus achievable.

According to a further embodiment of the invention, the base element and the cooling elements can have a density of at least 98% of the total density of the material used, whereby despite powder metallurgy manufacturing, the cooling device can have improved corrosion properties even without further post-processing. This is particularly advantageous for the cooling elements in which coolant is circulated during operation.

According to a further embodiment of the invention, it can be provided that the cooling elements have a height above the first surface of the base element of between 2 mm and 20 mm. Regarding the deformability, these heights of the cooling elements have proven to be advantageous because a more even material flow can be achieved across the entire height of the cooling elements.

According to one embodiment of the invention, it can be provided that one rear side of the base element is configured with a flat surface, whereby the contact of the base element can be improved on the one hand to a stamp during deformation and on the other hand to a cooling component during operation of the cooling device.

According to a further embodiment of the invention, it can be provided that at least one further structural element is arranged on the first surface of the base element which protrudes beyond the cooling elements in the height direction, and which is manufactured in net shape or near net shape quality. Here again, the powder metallurgy manufacturing of the cooling device is advantageous because further levels of the cooling device can be produced without intensive subsequent machining by already taking them into consideration when initially determining the shape of the preform.

### BRIEF DESCRIPTION OF THE DRAWINGS

For a better understanding of the invention, it is explained in more detail with reference to the following figures.

These show in simplified, schematic representation:

FIG. 1 shows a side view of a cooling device with the component to be cooled;

FIG. 2 shows an inclined view of a cooling device;

FIG. 3 shows an embodiment of a preform; and

FIG. 4 shows an embodiment of a tool for manufacturing the cooling device.

### DETAILED DESCRIPTION OF PREFERRED EMBODIMENTS

It is worth noting here that the same parts have been given the same reference numerals or same component configurations in the embodiments described differently, yet the disclosures contained throughout the entire description can be applied analogously to the same parts with the same reference numerals or the same component configurations. The indications of position selected in the description, such as above, below, on the side etc. refer to the figure directly described and shown, and these indications of position can be applied in the same way to the new position should the position change.

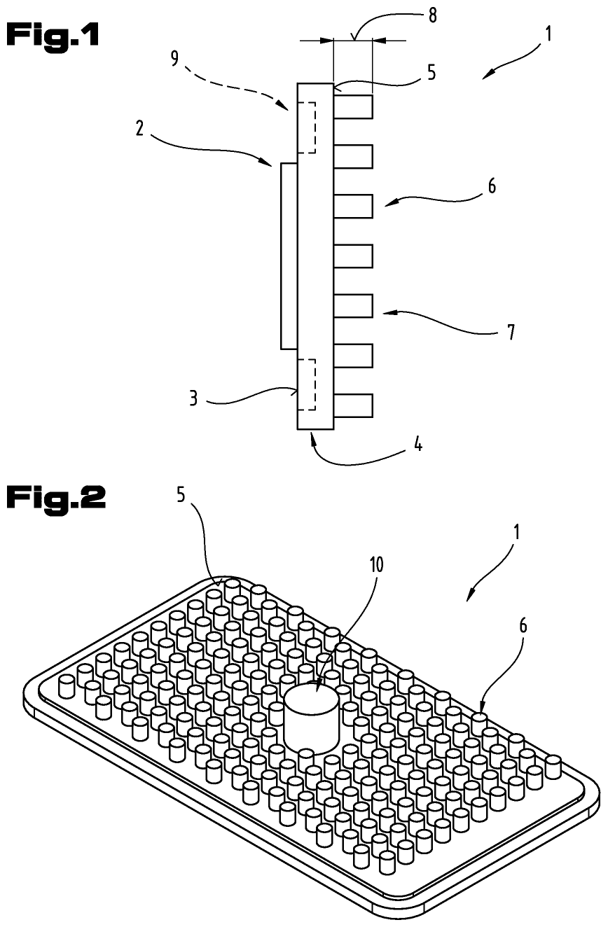

FIG. 1 shows a side view of a cooling device 1.

The cooling device 1 serves to cool a component 2 or multiple components 2 or an assembly. To do so, the cooling device is positioned with a rear side 3 in contact with the at least one component 2, in particular directly, and is thus preferably in direct contact with the component 2 for heat exchange.

The component 2 is preferably an electronic component, in particular what is known as a power electronics component or high-power electronics component, or a power semiconductor or high-power semiconductor. In particular, such components 2 or assemblies of/with these components 2 can be provided for power in the range of several kW to MW. Such components 2 serve, for instance, to convert electrical energy with switching electronic components. Typical applications are inverters or frequency inverters in the field of electrical drive technology, solar inverters and inverters for wind turbines for feeding regeneratively generated energy into the grid, or switching power supplies, generally the conversion of alternating current into direct current by rectifiers, the conversion of direct current into alternating current by inverters, controls, such as in the drive technology of an electric drive train of electric or hybrid vehicles, battery management systems, etc. A power electronics component can be a semiconductor, for example, in particular what is known as a power semiconductor, e.g., an IGBT.

Since such components 2 themselves are known from the relevant prior art, for the sake of avoiding repetition of such details, reference is hereby made to this prior art.

The cooling device 1 comprises a base element 4 which also forms the rear side 3 of the cooling device 1 and which has a cooling structure on its first surface 5, or rather consists of the base element 4 and the cooling structure. The cooling structure is formed by cooling elements 6 which are arranged on the base element 4 and protrude beyond the first surface 5 and are thus integrally connected, as can be seen from FIG. 2. In other words, the cooling device in the preferred embodiment is formed by one single piece. Irrespective of this one-piece configuration, according to the invention it is possible that per component 2 or assembly of/with at least one such component 2, multiple cooling devices 1 according to the invention can be combined with one another into a cooling device group. In particular, the cooling device 1 can thus also be combined modularly to form a cooling device group.

The base element 4 and the cooling elements 6 are manufactured from or consist of a sintering material. In addition, the cooling elements 6 are manufactured by deforming the base element 4.

In the preferred embodiment, the base element 4 and the cooling elements 8 have a density of at least 98%, in particular at least 98.5%, preferably at least 99% of the total density of the material used.

The total density thereby relates to the density of a cooling device manufactured from the same material using melting metallurgy, i.e. a component made from a solid material. A solid material thereby refers to a metallic material which, with the exception of flaws, has no pores, as is usually the case in sintered components.

It is intended for a cooling fluid, such as water, to circulate through the cooling elements 6, such that the heat absorbed by the cooling device 1 is transported away by this cooling fluid. Preferably, the cooling device 1 is a pin fin cooling device.

The cooling elements 6 in the embodiment shown are configured cylindrically. They can, however, have a different shape, such as a truncated cone shape or generally a cross section which tapers in the direction of a cooling element head 7, such as a truncated pyramid shape.

The cross section of the cooling elements 6 can be circular, oval, rhombic, square, etc.

In addition, all cooling elements 6 can have the same configuration. It is, however, possible to arrange or combine cooling elements 6 with different shapes on one base element 4.

The cooling elements 6 can preferably have a height 8 above the first surface 5 of the base element 4 which is between 2 mm and 20 mm.

In the simplest embodiment of the cooling device 1, all cooling elements 6 of the cooling device 1 have the same height 8 within the accepted tolerances. According to the invention it is, however, possible for part of the cooling elements 6 to have a lower height than the remaining cooling elements 6.

Furthermore, it can be provided that between 300 and 1300, in particular between 300 and 1000, for example between 300 and 750 cooling elements 6 are arranged or configured per dm² of the first surface. In particular, this number has proven to be advantageous with regard to the manufacture of the cooling device 1, i.e. the deformation of the base element 4 into cooling elements 6, because damages to the cooling elements 6 or incompletely formed cooling elements 6 can thereby be avoided or reduced.

As can be seen in particular in FIG. 1, according to one embodiment of the cooling device 1, it can be provided that the rear side 3 of the base element 4 is configured with a flat surface. It is, however, also possible that the rear side 3 is configured with one or more indentations 9 which at least partially receive a component 2. A better connection of the component 2 to the cooling device 1 can thus be achieved. Generally, the component 2 can be glued or screwed or soldered or sintered, etc., to the cooling device 1.

The at least one indentation 9 can be manufactured simultaneously with the manufacture of the cooling elements 6. Due to the at least one indentation 9, it is also possible to manufacture cooling elements 6 whose height 8 is greater than that of the remaining cooling elements 6.

As can be seen in FIG. 2, the cooling device 1 on the first surface 5 of the base element 4 can have at least one further structural element 10. The structural element 10 is a cylinder in the represented embodiment, but it can also have a different cross-sectional surface, such as a rhombus. With the structural element 10, a further surface 11 can be provided on the cooling device 1 which is positioned above the level of the cooling elements 6. The structural element 10 can therefore have a greater height than the cooling elements 6. It is, however, also possible that the at least one structural element 10 has a lesser or the same height as the cooling elements 6. In addition, more than one structural element 10 can be arranged, where the multiple structural elements 10 can have the same or a different configuration, e.g. shape and/or height.

The structural element 10 can, for instance, be provided for a screw connection, as reinforcement, or as a spacer or end stop.

The structural element 10 is preferably not mechanically post-processed, rather it is co-pressed or powder metallurgically manufactured in net shape or near net shape quality during the pressing of the preform for manufacturing the cooling device 1. The structural element 10 or the structural elements 10 are thus preferably configured as a single piece with the base element 4 and the cooling elements 6.

A sintering powder or a powder, in particular a metallic powder, used in powder metallurgy, is used to manufacture the cooling device 1. Preferably, a sintering powder is used which has correspondingly good heat conductivity. In particular, a sintering powder which is based on aluminum or an aluminum alloy, or which is based on copper or a copper alloy, is used, or an MMC powder (metal matrix composite) is used.

The manufacture of the cooling device is performed in a powder metallurgy manner according to a powder metallurgy method, and is thus preferably a sintered component. To do so, a green body is manufactured in a corresponding press mold (die) from a sintering powder which can be made by mixing the individual (metallic) powders, whereby the powders can be used as pre-alloys where necessary. Preferably, the green body has a density of at least 80%, in particular between 80% and 96%, of the total density of the material.

The green body is subsequently dewaxed at the standard temperatures and then sintered in a one, two or multiple step process, and then preferably cooled to room temperature. For example, the sintering can be performed at a temperature between 500° C. and 1300° C.

Since these method steps and the method parameters used therein are also known in the prior art, to avoid repetition reference is hereby made to the relevant prior art.

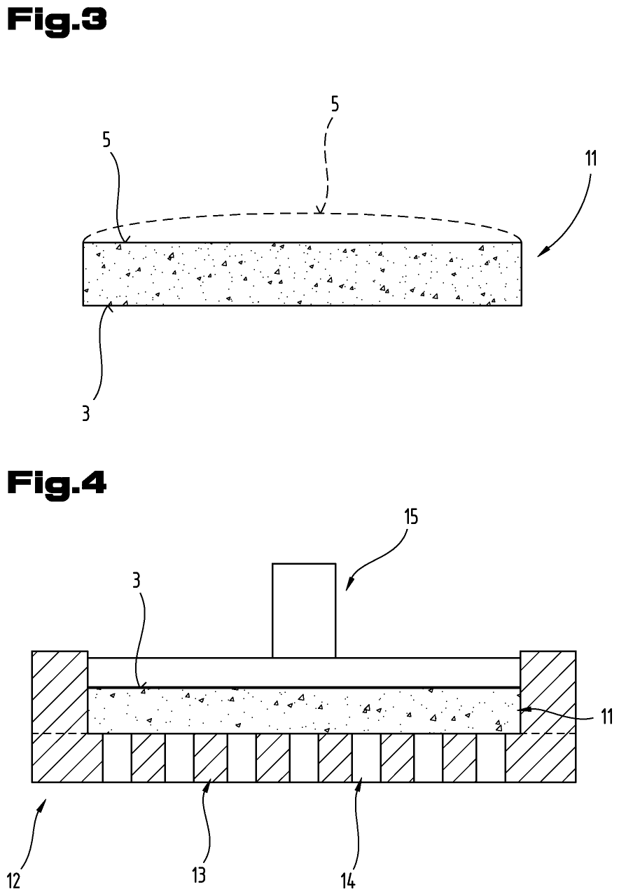

Through sintering, a preform 11 is obtained from the green body, as shown as an example in FIG. 3. The preform 11 can be configured as a flat plate such that the rear side 3 and the first surface 5 can thus run parallel to one another.

According to one embodiment of the invention, it can be provided that the first surface 5 of the preform upon which the cooling structure is formed is produced to be at least partially arched. Other shapes of the first surface of the preform 11 are possible with a view to the improved deformability of the preform 11. For instance, first pin fin formations or cooling element formations (circular, oval, ellipsoid, etc.) with a height between 0.1 mm and 2.0 mm can already be preformed. In addition, structures (waves, ribs etc.) can be intentionally incorporated into the surface 5 of the preform to potentially increase the fluidization of a cooling fluid.

The preform 11 can be subsequently re-pressed. Preferably, however, the re-pressing is performed simultaneously with the deformation of the preform 11 into the cooling elements 6.

The deformation of the preform 11 is carried out in a mold 12. The preform is thereby placed into or onto the mold 12. In the simplest case, the mold 12 is formed by a perforated plate 13. The perforated plate 13 has recesses 14, in particular openings, into or through which a part of the material of the preform 11 is pushed, thereby forming the cooling elements 6. The rest of the material of the preform 11 which is not pressed into or through the mold 12 forms the base element 4.

The recesses 14, i.e. their cross section, is adjusted accordingly to the cross section of the cooling elements 6 to be manufactured.

The mold 12 can also be configured differently, that is to say, it need not necessarily be a simple perforated plate 13. In particular, for best performance the mold 12 can be configured as a die.

For the case that at least one further structural element 10 is present, this can be accounted for with a corresponding recess or a corresponding opening in the mold 12.

For deformation, a stamp 15 is placed onto the rear side 3 of the preform 11, which also forms the rear side 3 of the base element 4, and is pressed onto the preform 11 with a predetermined pressure. For example, the deformation can be performed at a pressure of between 700 MPa and 1600 MPa. Moreover, the deformation can be performed over a period of up to 10 seconds, in particular between 0.1 seconds and 10 seconds. Furthermore, the deformation is preferably performed at room temperature (20° C.), i.e. cold, or the deformation can also be performed following pre-heating of the preform 11 to a temperature between 50° C. and 300° C., for example between 50° C. and 150° C. and/or in/with a mold 12 heated to a temperature between 50° C. and 300° C., for example between 50° C. and 150° C.

After molding, i.e. deformation of the preform 11, the cooling device 1 can be finished. It is, however, possible to post-process the cooling device 1.

The example embodiments show possible embodiment variations, although it is to be noted here that combinations of the individual embodiment variations with one another are possible.

As a matter of form and by way of conclusion, it is noted that, to improve understanding of the structure of the cooling device 1 or mold 12, they are not necessary shown to scale.

### LIST OF REFERENCE NUMERALS

1 Cooling device
2 Component
3 Rear side
4 Base element
5 Surface
6 Cooling element
7 Cooling element head
8 Height
9 Indentation
10 Structural element
11 Preform
12 Mold
13 Perforated plate
14 Recess
15 Stamp

What is claimed is:

1. A method for manufacturing a cooling device (1) comprising the steps of providing a material and forming a cooling structure from the material, wherein a sintering powder is used as the material from which a green body is manufactured by pressing, wherein the green body is sintered into a preform (11), and the cooling structure in the form of cooling elements (6) is manufactured from the preform (11) by deformation, whereby a part of the preform (11) is pressed through a mold (12).

2. The method according to claim 1, wherein the preform (11) is re-pressed and that the cooling structure is formed during re-pressing.

3. The method according to claim 1, wherein the cooling structure is manufactured in the form of pin-shaped cooling elements (6) using a perforated plate (13) as a mold (12).

4. The method according to claim 1, wherein the surface of the preform (11) upon which the cooling structure is formed is produced to be at least partially arched.

5. A cooling device (1) for cooling components (2) comprising a base element (4) with a first surface (5), and with a cooling structure with cooling elements (6) which is arranged on the base element (4) protruding beyond the first surface (5), wherein the base element (3) and the cooling elements (6) comprise a sintering material and wherein the cooling elements (6) are manufactured from the material of the base element (3) by deformation.

6. The cooling device (1) according to claim 5, wherein the base element (4) and the cooling elements (6) have a density of at least 98% of the total density of the material used.

7. The cooling device (1) according to claim 5, wherein the cooling elements (6) have a height (8) above the first surface (5) of the base element (4) of between 2 mm and 20 mm.

8. The cooling device (1) according to claim 5, wherein a rear side (3) of the base element (4) is configured with a flat surface.

9. The cooling device (1) according to claim 5, wherein at least one further structural element (10) is arranged on the first surface (5) of the base element (4) which protrudes beyond the cooling elements (6) in the height (8) direction, and which is manufactured in net shape or near net shape.
